(19) United States
(12) Patent Application Publication
(10) Pub. No.: US 2013/0154663 A1
(43) Pub. Date: Jun. 20, 2013

(54) LENS MODULE ELECTRICAL TESTING SYSTEM AND TESTING METHOD

(71) Applicants: YU-HAN CHEN, Tu-Cheng (TW); MENG-YU TSAI, Tu-Cheng (TW)

(72) Inventors: YU-HAN CHEN, Tu-Cheng (TW); MENG-YU TSAI, Tu-Cheng (TW)

(73) Assignee: HON HAI PRECISION INDUSTRY CO., LTD., Tu-Cheng (TW)

(21) Appl. No.: 13/589,298

(22) Filed: Aug. 20, 2012

(30) Foreign Application Priority Data
Dec. 19, 2011 (TW) 100147107

(51) Int. Cl. G01R 31/02

(52) U.S. Cl. 324/537

(57) ABSTRACT

A lens module electrical testing system is set up and configured for testing lens modules. The lens module electrical testing system includes a circuit board, a LCR meter connecting with the circuit board, and a program controller connecting with the circuit board. The circuit board includes an electrical connecting portion and a microcontroller. The electrical connecting portion connects with the lens module. The program controller sends programs to the microcontroller. The microcontroller sends a control command to the LCR meter. The LCR meter tests the electrical properties of the lens module, and then determines the quality of the lens module corresponding to the control command by pass or fail. The present disclosure further provides a testing method for testing lens modules using the lens module electrical testing system.

### BACKGROUND

1. Technical Field

The present disclosure relates to lens module testing systems, particularly to a lens module electrical testing system and a testing method for testing a lens module using the lens module electrical testing system.

2. Description of Related Art

A lens module, such as a lens module for a mobile phone and so on, includes a plurality of test points, for testing properties of the lens module via measuring the electrical parameters between the test points, such as for testing the focusing properties of the lens module, for example. Testing of the lens module is performed manually, which results in the testing being of too time consuming. In addition, the manual testing may miss a test step.

Therefore, there is room for improvement in the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views, and all the views are schematic.

FIG. 1 is a schematic view of an embodiment of a lens module electrical testing system.

FIG. 2 is a flow chart of an automatic test method for testing lens modules using the lens module electrical testing system shown in FIG. 1.

FIG. 3 is a block diagram of the lens module electrical testing system shown in FIG. 1.

### DETAILED DESCRIPTION

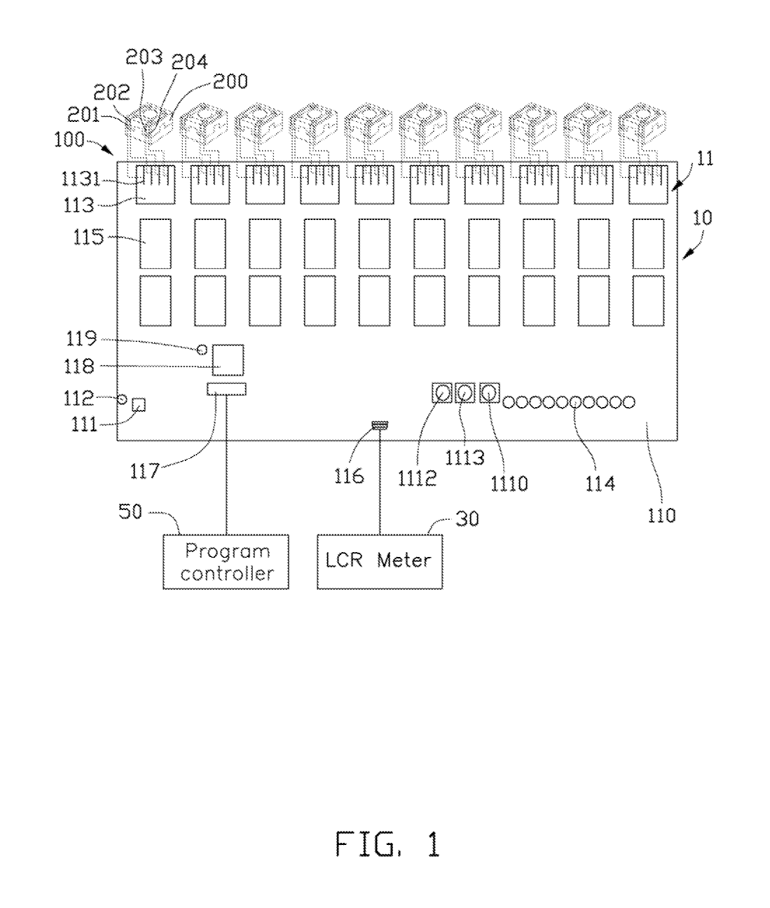

FIG. 1 shows an embodiment of a lens module electrical testing system 100. The electrical testing system 100 is configured for electrically testing at least one lens module 200. The lens module 200 includes a plurality of test points. In the illustrated embodiment, the lens module 200 is a lens module configured for a mobile phone, and there are four test points on a sidewall of the lens module 200. The four test points are defined as a first test point 201, a second test point 202, a third test point 203, and a fourth test point 204. The lens module electrical testing system 100 measures an alternating current capacity and an alternating current resistance between the first test point 201 and the third test point 203, and measures a direct current resistance between the second test point 202 and the fourth test point 204, and then tests the focusing properties of the lens module 200 by determining if the measured capacity and resistance values would satisfy the required parameters. In other embodiments, the number of the test points of the lens module 200 can be two, three, five, or more, for example.

The lens module electrical testing system 100 includes a circuit board 10, an Inductance Capacitance Resistance meter 30 (LCR meter 30), and a program controller 50. The circuit board 10 electrically connects the four test points 201-204 of the lens module 200. The LCR meter 30 and the program controller 50 are also electrically connected to the circuit board 10. The program controller 50 inputs programs to the circuit board 10. The LCR meter 30 measures and determines the electrical parameters of the lens module 200 corresponding to the programs, and feeds back the results to the circuit board 10.

The circuit board 10 includes a base plate 110, a plurality of electrical components 11 mounted on the base plate 110, and a circuit (not shown) covered on the base plate 110. The electrical components 11 are electrically connected with the circuit.

The electrical components 11 include a power switch 111, a power indicator light 112, an electrical connecting portion 113, a test indicator light 114, a relay 115, a connecting port 116, a program input port 117, a microcontroller 118, a microcontroller indicator light 119, a start button 1110, a loop switch 1112, a shut off button 1113, and a testing mode selection button (not shown). The electrical components 11 are prearranged on the base plate 110.

The power switch 111 controls the communication of the circuit. The power indicator light 112 indicates the communication state of the circuit. The electrical connecting portion 113 includes four electrical pins 1131, for electrically connecting with the four test points 201-204 of the lens modules 200. In the illustrated embodiment, there are ten electrical connecting portions 113, and the ten electrical connecting portions 113 are separately arranged on an edge of the base plate 110 in a predetermined manner, for conveniently connecting with ten lens modules 200.

In the illustrated embodiment, there are ten test indicator lights 114 corresponding to the electrical connecting portions 113. Each test indicator light 114 communicates with a corresponding electrical connecting portion 113, and forms a test loop (not shown) with the electrical connecting portion 113. The test indicator lights 114 indicates the condition of the lens modules 200. If the lens module 200 is rejected due to defective condition, the corresponding test indicator light 114 goes out.

In the illustrated embodiment, there are twenty relays 115, and a pair of relays 115 are arranged at each test loop. Each pair of relays 115 is located between the corresponding test indicator light 114 and the corresponding electrical connecting portion 113, for protecting the test loop. The connecting port 116 is configured for connecting the LCR meter 30 with the circuit board 10. In the illustrated embodiment, the connecting port 116 is a RS232 port. The program input port 117 is configured for connecting the program controller 50 with the circuit board 10. The program controller 50 provides programs to the microcontroller 118. The microcontroller 118 sends a control command to the LCR meter 30, to control the LCR meter 30 to measure the electrical parameters of the lens modules 200 corresponding to the program input by the program controller 50. The microcontroller indicator light 119 indicates the working state of the microcontroller 118.

The start button 1110 controls the starting or actuating of the test loop. The testing mode selection button is configured for selecting between an automatic testing or a manual testing mode. The shut off button 1113 controls the shut off or turn off of the test loop, and switches between the testing of different test points when performing manual testing. The loop switch 1112 switches to a different test loop when performing under manual testing mode.

The LCR meter 30 pre-stores the required test parameters. The LCR meter 30 receives the control command from the microcontroller 118, and then starts testing the alternating current resistance between the first test point 201 and the third test point 203, and the direct current resistance between the second test point 201 and the fourth test point 204. In addition, the LCR meter 30 determines if the measured parameters satisfy the required parameters, and then feeds back the results to the microcontroller 118. Thus the microcontroller 118 controls the test indicator light 114 to indicate the results.

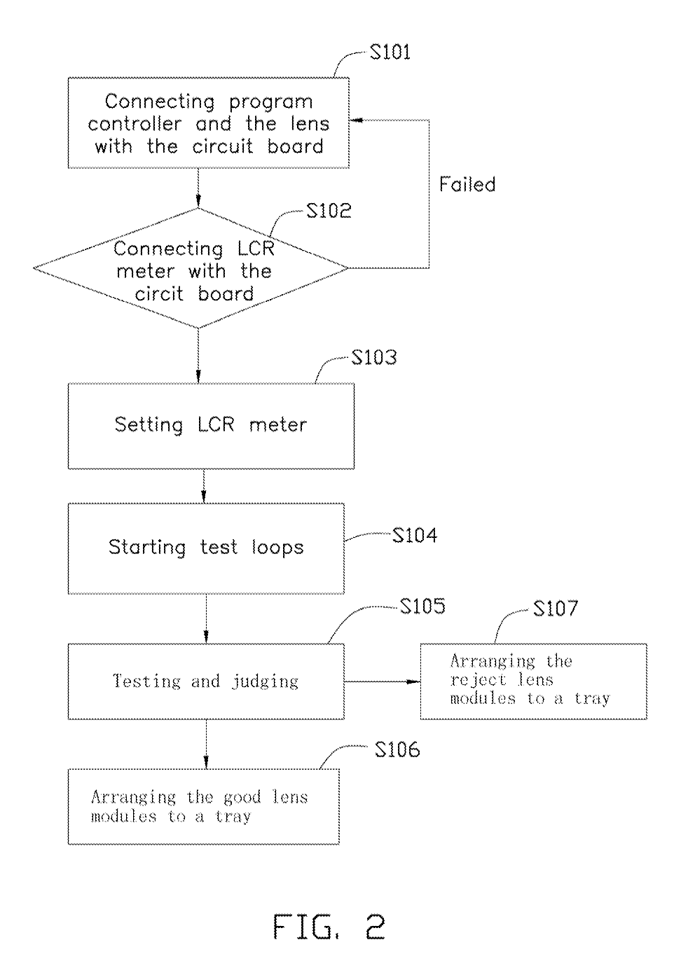

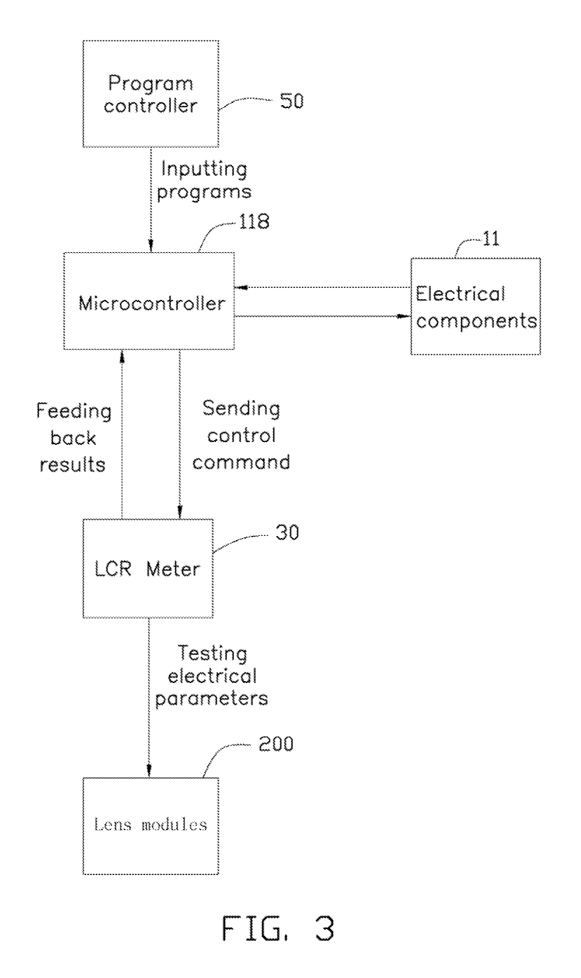

FIGS. 2 and 3 show an automatic test method of lens modules using the lens module electrical testing system 100. The steps of the testing method are as follows.

In step S101, the lens modules 200 are connected to the corresponding electrical connecting portion 113, and the program controller 50 is connected to the circuit board 10. The first test point 201, the second test point 202, the third test point 203, the fourth test point 204 are connected to the four electrical pins 1131, respectively. The program controller 50 is inserted to the program input port 117. Manually pressing the power switch 111 charges the circuit board 10. The program controller 50 inputs programs to the microcontroller 118 through the program input port 117.

In step S102, the LCR meter 30 is connected to the circuit board 10. The LCR meter 30 is inserted to the connecting port 116, and then the LCR meter 30 communicates with the test loops. When the LCR meter 30 fails to connect to the circuit board 10, the LCR meter 30 is reconnected to the circuit board 10 to ensure that the LCR meter 30 electrically connects to the electrical pins 1131 and the lens modules 200.

In step S103, a plurality of required parameters for the LCR meter 30 are set, and automatic testing mode is selected. The required parameters of alternating current capacity, alternative current resistance, and direct resistance via outputting an output frequency are set. In the illustrated embodiment, the output frequency of the LCR meter 30 is set as 10 kHz. Accordingly, the required parameter of the alternating current resistance between the first test point 201 and the third test point 203 is 10 kΩ to 100 kΩ, the required parameter of the alternating current capacity between the first test point 201 and the third test point 203 is 395 pF to 480 pF, and the required parameter of the direct current resistance between the second test point 202 and the fourth test point 204 is 180Ω to 400Ω. In other embodiments, the output frequency of the LCR meter 30 can be of other frequencies, and the electrical parameters are changed corresponding to the output frequency.

In step S104, the test loop is activated or started. The start button 1110 is pressed to start the test loop. The microcontroller 118 sends commands to the LCR meter 30.

In step S105, the LCR meter 30 tests the lens modules 200 and determines if the lens modules are to be passed or rejected according to their respective quality conditions and required parameters. The LCR meter 30 tests and measures the alternating current capacity and resistance between the first test point 201 and the third test point 203, and the direct current resistance between the second test point 202 and the fourth test point 204 corresponding to the command send from the microcontroller 118, and then determines if the alternating current capacity, the alternating current resistance and the direct current resistance measurements satisfy the required parameters, and further feeds back the determined measurement results to the microcontroller 118. The microcontroller 118 controls the test indicator light 114 to indicates the determined results. That is, if the measured parameter results satisfy the required parameters, the lens module 200 is determined to be a good lens module (pass), and the corresponding test indicator light 114 lights on; if the measured parameter results do not satisfy the required parameters, the lens module 200 is determined to be rejected, and the corresponding test indicator light 114 goes out.

In step S106, the good lens modules (pass) and the rejected lens modules (fail) are arranged apart. In the illustrated embodiment, the good/passing lens modules and the rejected/failed lens modules are put into different trays (not shown). If all lens modules have been tested, the shut off button is manually pressed to shut off the test loop. The test indicator lights 114 are turned off at the same time.

A manual testing method is similar to the automatic testing method described above. The differences of the manual testing method as follows. Manual testing is selected in step 103. The loop switch 1112 is pressed to choose a desired test loop after starting the test loop in step 104, and the test indicator light 114 corresponding to the chosen test loop lights. After testing and measuring the parameters between the first test point 201 and the third test point 203, the shut off button 1113 is pressed for about 2 or 3 seconds to change to testing and measuring the parameter between the second test point 202 and the fourth test point 204, and all of the test indicator lights 114 flash three times, at the same time.

The lens module electrical testing system 100 tests the lens modules 200, and indicates the tested results via the test indicator lights 114, thereby easily assessing as to which lens modules 200 are rejected/failed. In addition, the lens module electrical testing system 100 can be switched to operate automatically or manually to test the lens modules 200. When automatic mode is chosen, the lens modules 200 are be quickly automatically tested via the LCR meter 30, to achieve a higher testing speed and provide time savings. When manual mode is chosen, the testing parameters of the lens modules 200 are manually switched from one to another, thus achieving to debug each lens module 200 and increase the testing precision.

It is believed that the present embodiments and their advantages will be understood from the foregoing description, and it will be apparent that various changes may be made thereto without departing from the spirit and scope of the embodiments or sacrificing all of its material advantages.

What is claimed is:

1. A lens module electrical testing system for testing at least one lens module, comprising:
a circuit board comprising a base plate, a plurality of electrical components arranged on the base plate, and a circuit covered on the base plate, the electrical components electrically connected to the circuit of the circuit board, the plurality of electrical components comprising at least one electrical connecting portion and a microcontroller, the at least one electrical connecting portion electrically connected to the lens module;
a LCR meter connected to the circuit board, for testing one or more parameters of the lens module, the LCR meter pre-storing the required parameters; and
a program controller connected to the circuit board for providing a plurality of programs to the microcontroller;
wherein the microcontroller is configured to send a control command to the LCR meter according to the programs, the LCR meter receives the control command to start testing and measuring the parameters of the lens module corresponding to the control command, and determines if the measured parameters satisfy the required parameters.

2. The lens module electrical testing system of claim 1, wherein the plurality of electrical components further comprises at least one test indicator light, the at least one test indicator light communicates with the at least one electrical connecting portion, and forms a test loop with the electrical connecting portion, the LCR meter feeds back the determined results of the measured electrical parameters to the microcontroller, and the microcontroller controls the test indicator light to indicate the properties of the lens module.

3. The lens module electrical testing system of claim 2, wherein the plurality of electrical components further comprises a start button, for starting the test loop.

4. The lens module electrical testing system of claim 2, wherein the plurality of electrical components further comprises at least one relay, the at least one relay is arranged at the test loop, and is located between the at least one test indicator light and the at least one electrical connecting portion, for protecting the test loop.

5. The lens module electrical testing system of claim 1, wherein the required parameters in the LCR meter is capable of being set corresponding to an output frequency of the LCR meter.

6. The lens module electrical testing system of claim 2, wherein the plurality of electrical components further comprises a testing mode selection button, for selecting between an automatic testing mode or a manual testing mode to test the lens module.

7. The lens module electrical testing system of claim 6, wherein the plurality of electrical components further comprises a loop switch, the loop switch chooses between a plurality of different test loops when performing under the manual testing mode.

8. The lens module electrical testing system of claim 6, wherein the at least one electrical connecting portion further comprising a plurality of electrical pins, the electrical pins are electrically connected with the test points of the lens module.

9. The lens module electrical testing system of claim 8 wherein the plurality of electrical components further comprises a shut off button, the shut off button controls the turning off of the test loop, and switches between the test of different test points when performing under manual testing mode.

10. A testing method for testing one or more lens module using the lens module electrical testing system of claim 6, comprising the following steps:
connecting the lens module with the electrical connecting portion, and connecting the program controller with the circuit board, the program controller inputting programs to the microcontroller;
connecting the LCR meter with the circuit board;
setting the LCR meter, and pre-storing a plurality of required parameters in the LCR meter, and selecting an automatic testing mode;
starting the test loop, and the microcontroller sending a control command to the LCR meter;
testing and measuring parameters using the LCR meter; and
determining if the lens modules to be passed or rejected according to the programs and the required parameters.

11. The testing method of claim 10, wherein the testing method further comprising following step:
feeding the determined results of the measured electrical parameters from the LCR meter back to the microcontroller.

12. A testing method for testing a lens module using the lens module electrical testing system of claim 6, comprising the following steps:
connecting the lens module with the electrical connecting portion, and connecting the program controller with the circuit board, the program controller inputting programs to the microcontroller;
connecting the LCR meter with the circuit board;
setting the LCR meter, and pre-storing a plurality of required parameters in the LCR meter, and selecting a manual testing mode;
starting the test loop, and sending a control command to the LCR meter by the microcontroller;
testing and measuring the parameters using the LCR meter and determining if the lens modules to be passed or rejected according to the programs and the required parameters.

13. The testing method of claim 12, wherein the testing method further comprising following step:
feeding the determined results of the measured electrical parameters from the LCR meter back to the microcontroller.

14. The testing method of claim 12, wherein the plurality of electrical components further comprises a loop switch, and the testing method further comprising another step: pressing the loop switch to choose a different test loop.

15. The testing method of claim 12, wherein the plurality of electrical components further comprises a shut off button, and the testing method further comprising another step: pressing the shut off button to control the turning off of the test loop, and to switch the test of different test points.
